(19) United States
(12) Patent Application Publication
(10) Pub. No.: US 2014/0132357 A1
(43) Pub. Date: May 15, 2014

(54) Broadband Distributed Transmission Line N-Path Filter

(71) Applicants: University of California, La Jolla, CA (US); Brown University, Providence, RI (US)

(72) Inventors: Lawrence E. Larson, Providence, RI (US); Chris Michael Thomas, La Jolla, CA (US)

(73) Assignees: University of California, La Jolla, CA (US); Brown University, Providence, RI (US)

(21) Appl. No.: 14/075,705

(22) Filed: Nov. 8, 2013

Related U.S. Application Data
(60) Provisional application No. 61/724,255, filed on Nov. 8, 2012.

(51) Int. Cl. H03H 7/01; H03F 1/56

(52) U.S. Cl. CPC H03H 7/0138; H03H 7/0115; H03F 1/565
USPC 330/303; 333/168

(57) ABSTRACT

In an embodiment, a single-ended transmission line N-path filter includes one or more filter stages, each stage having a first series inductive element, a shunt N-path filter, and a second series inductive element; an input port; and an output port.

### RELATED APPLICATION

This application claims the benefit of U.S. Provisional Application No. 61/724,255, filed on Nov. 8, 2012. The entire teachings of the above application are incorporated herein by reference.

### GOVERNMENT SUPPORT

This invention was made with government support under contract number N66001-11-C-4159 from United States Department of the Navy's Space and Naval Warfare Systems Command (SPAWAR) Systems Center. The government has certain rights in the invention.

### TECHNICAL FIELD

The present invention is in the general field of filters and in some embodiments relates to improvements in receiver front end filters.

### BACKGROUND

Receiver complexity has grown due to the multi-band nature of cellular technology and newly available opportunity for cognitive radio applications in un-occupied TV bands. Over thirty bands are currently envisioned for many mobile phone applications and several dozen TV bands are available for cognitive radio. Such broad-band frequency coverage makes the receiver susceptible to out-of-band jammers desensitizing the receiver and requiring many off-chip band-selecting filters. Current cellular technology often employs SAW filter banks for each band which, while having good out-of-band rejection and insertion loss, are large and costly. To meet the future needs of growing receiver complexity and desired agility, a fully integrated, highly tunable front-end filter for out-of-band jammer robustness is desired.

### SUMMARY

A potential candidate for a front-end filter is the N-path filter. The N-path filter's performance is limited by shunt parasitic capacitance, which increases the insertion loss, and the switch resistance, which limits the filter's rejection. Embodiments of a broad-band distributed transmission line N-path filter in accordance with the present disclosure absorb the N-path filter's shunt parasitic capacitance, reducing in-band insertion loss, and allow for multiple cascaded filter stages for increased out-of-band rejection. A distributed transmission line N-path filter lowers the in-band insertion loss and increases the out-of-band rejection of the traditional N-path filter.

In an embodiment, a single-ended transmission line N-path filter includes one or more filter stages, each stage having a first series inductive element, a shunt N-path filter, and a second series inductive element; an input port; and an output port.

In another embodiment, a differential transmission line N-path filter includes one or more filter stages, each stage including a first leg having a first inductive element connected in series with a second inductive element at a first node and a second leg running parallel to the first leg, the second leg having a third inductive element connected in series with a fourth inductive element at a second node. A differential shunt N-path filter is connected between the first node of the first leg and the second node of the second leg. The differential filter further includes an input port and an output port.

In some embodiments, each N-path filter is driven by non-overlapping clocks.

The inductive elements may include spiral inductors or waveguide inductors.

In another embodiment, a circuit includes a transmission line N-path filter having an input port, and output port, and one or more filter stages; and a low noise amplifier connected to the output port of the transmission line N-path filter.

### BRIEF DESCRIPTION OF THE DRAWINGS

The foregoing will be apparent from the following more particular description of example embodiments, as illustrated in the accompanying drawings in which like reference characters refer to the same parts throughout the different views. The drawings are not necessarily to scale, emphasis instead being placed upon illustrating embodiments.

FIG. 1A shows a single-ended N-path filter with high Q band-pass response.

FIG. 1B shows a fully differential N-path filter with high Q band-pass response.

FIG. 2A shows a single-ended transmission line filter with K stages.

FIG. 2B shows a fully differential transmission line filter with K stages.

FIG. 3 shows an example S₂₁ response of N=8 single-ended N-path filter (switches W/L=320 um/65 nm) versus clock Local Oscillator (LO) frequency (in 1 GHz steps) and lumped transmission line with K=4, C=500 fF=8*Cₚₐᵣ and L=1.25 nH (Q approximately 14 and self-resonance approximately 20 GHz).

FIG. 4 shows an example S₂₁ response with varying device widths for the single-ended N-path filter (LO=3 GHz, Rₛ=50 Ω, and Lg=65 nm).

FIG. 5A illustrates an example embodiment of a single-ended distributed transmission line band-pass N-path filter with K N-path stages in accordance with the present invention.

FIG. 5B illustrates an example embodiment of a differential distributed transmission line band-pass N-path filter with K N-path stages in accordance with the present invention.

FIG. 6A shows an example S₂₁ response for the single-ended N-path filter and the single-ended distributed transmission line band-pass N-path filter with K=4, where the clock LO is swept in 1 GHz steps, N=8, and total device size is W=320 um, Lg=65nm.

FIG. 6B shows an example S₁₁ response for the single-ended N-Path filter and the single-ended distributed transmission line band-pass N-path filter with K=4, where the clock LO is swept in 1 GHz steps, N=8, and total device size is W=320 um, Lg=65nm.

FIG. 6C shows an example S₂₁ response at LO (or, in-band insertion loss) for the single-ended N-Path filter and the single-ended distributed transmission line band-pass N-path filter with K=4, where the clock LO is swept in 1 GHz steps, N=8, and total device size is W=320 um, Lg=65 nm.

FIG. 7A shows an example embodiment of a single-ended distributed transmission line band-pass N-path filter with Low Noise Amplifier (LNA).

FIG. 7B shows an example embodiment of a single-ended distributed transmission line band-pass N-path filter with broad-band resistive feed-back Low Noise Amplifier (LNA).

FIG. 8A illustrates an example measured S₂₁ response sweeping the clock frequency from 300 MHz to 1600 MHz.

FIG. 8B illustrates an example measured S₁₁ response sweeping the clock frequency from 300 MHz to 1600 MHz.

FIG. 8C illustrates an example measured gain compression at 1 GHz with out-of-band jammer at 230 MHz offset.

### DETAILED DESCRIPTION

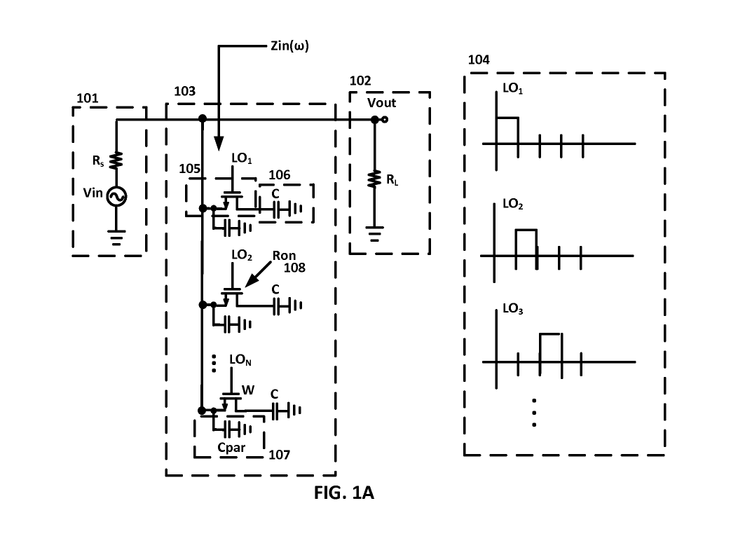

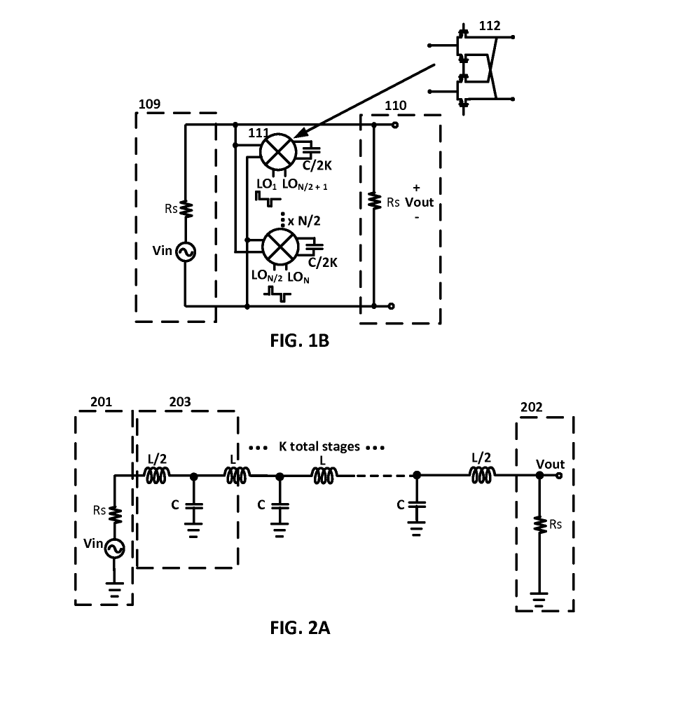

A potential candidate for a front-end filter is the N-path filter, shown as a single-ended filter in FIG. 1A and fully differential filter in FIG. 1B, which translates a base-band impedance to the switching frequency of the driving non-overlapping clock 104. The N-path filter is a two-port network (either single-ended FIG. 1A or fully differential FIG. 1B) with input port 101/109 and output port 102/110. For the differential N-path filter, a differential passive mixer 111/112 is used to translate the base-band impedance to the switching frequency. The N-path filter stage 103 is placed in shunt to the input port 101/109 and output port 102/110. With a base-band capacitive impedance 106, a high Q, band tunable band-pass filter is created. The N-path filter's high frequency performance is limited by switch shunt parasitic capacitance, Cₚₐᵣ 107, which increases the in-band insertion loss, and the switch resistance, Rₒₙ 108, of filter switch 105, which limits the out-of-band rejection.

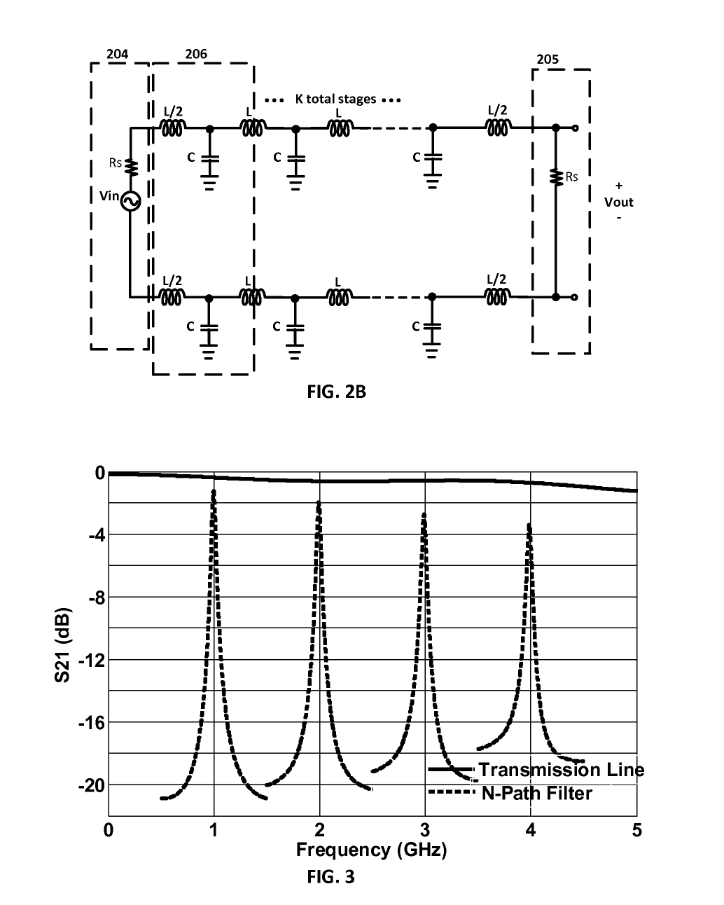

A broad-band transmission line is a two-port circuit (either single-ended as in FIG. 2A or differential as in FIG. 2B) comprising a series inductive element, shunt capacitive element, and a second series inductive element in a “T” network 203/206 which is cascaded K times. The series line inductance is chosen to absorb the shunt parasitic capacitance, creating an ideal lossless path below the cut-off frequency of the line. Additionally, the input 201/202 and output 204/205 ports of the transmission line are power matched, designed to a particular characteristic impedance Rs. Specifically, a

broad-band transmission line has a characteristic impedance of

$${Z}_{o} = \sqrt{\frac{L}{C}}$$

and cut-off frequency of

$${ω}_{c} = \frac{1}{\sqrt{LC}} .$$

An example plot of the S₂₁ response for the N-path filter (FIGS. 1A, 1B) and transmission line (FIGS. 2A, 2B) is shown in FIG. 3. As shown in FIG. 3, the N-path filter's in-band insertion loss at higher clock frequency increases due to the parasitic capacitances of the switches while the transmission line filter has minimal insertion loss up to several GHz.

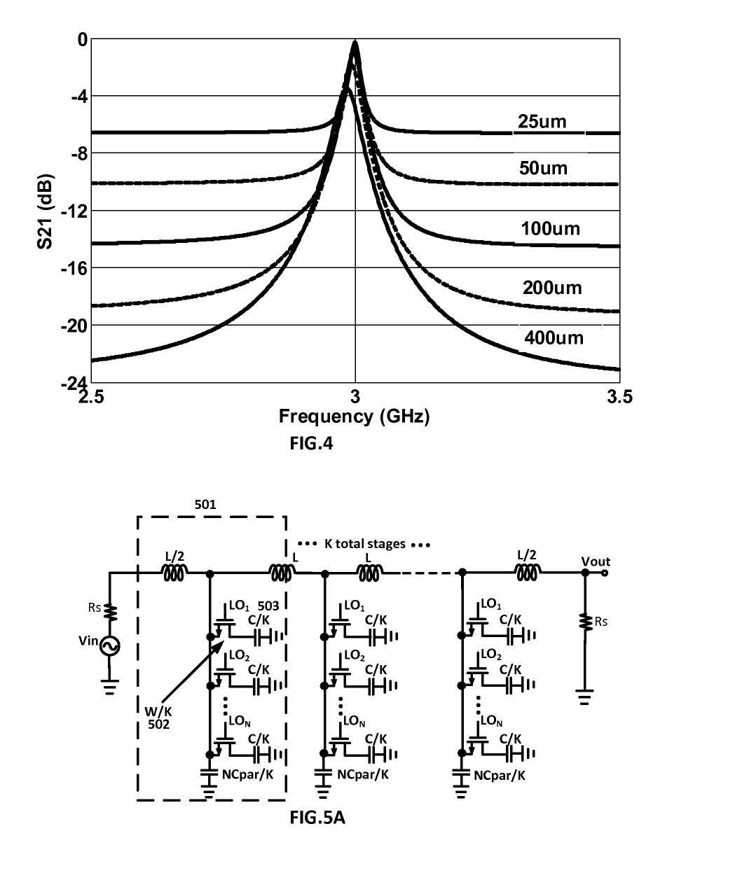

FIG. 4 shows an example S₂₁ response with varying device widths for the single-ended N-path filter demonstrating the performance trade-off with this filter approach. As the FET switch width increases, to improve the out-of-band rejection, the in-band insertion loss also rises (due to increased parasitic capacitance of the switches). The added pass-band loss associated with the parasitic capacitance is approximately 1/(1+sRₛNCₚₐᵣ) and the resulting out-of-band rejection is approximately S₂₁(s)≈Rₒₙ/Rₛ, which is limited by Rₒₙ.

A filter topology that takes advantage of the N-path filter's high-Q tunable filtering and the transmission line's broad-band operation is desired. To significantly improve the high frequency performance, the parasitic capacitance of the N-path filter (107) can be incorporated into a synthetic transmission line, broad-banding the filter response significantly. A single-ended distributed transmission line N-path filter (TLNF) is shown in FIG. 5A and a differential TLNF is shown in FIG. 5B. The TLNF is a multi-stage filter that includes multiple (e.g., K) N-path filter stages, each TLNF stage including a first series inductive element, a shunt N-path filter, and a second series inductive element, forming a “T” network 501/504. The inductive elements may be realized by, but not limited to, integrated spiral inductors or micro-strip wave-guide inductors operating from RF to mm-wave. The N-path filter switch may be implemented in various technologies (bulk CMOS as illustrated, GaN, SOI, etc.) depending on the desired performance such as power handling and frequency range of operation. In a particular embodiment, the N-path filter in the “T” network has a device width (502) and base-band capacitor (503) of W/K and C/K, respectively, to distribute the parasitic capacitance of the N-path filter on the transmission line. In a particular embodiment of the TLNF, the inductance L is chosen to provide the characteristic impedance of Rₛ=\sqrt{L/(NCₚₐᵣ/K)} and the resulting cut-off frequency is ω_{c}=1/\sqrt{L(NCₚₐᵣ/K)}.

The out-of-band S₂₁ of a multi-stage band-pass lumped TLNF is approximated by

$${S}_{21} ( s ) \approx \frac{8 {R}_{s} {R}_{on}^{K}}{{s}^{K + 1} {L}^{K + 1} ( 1 + {s}^{- 1} {L}^{- 1} ( ( 2 K + 2 ) {R}_{on} + 4 {R}_{s} ) )} ,$$

where Rₒₙ is the switch ON resistance, Rₛ is the port impedance, and K is the number of stages. At high frequencies, S₂₁(S)≈8RₛRₒₙ^{k}/(s^{K+1}L^{K+1}), which is superior to a traditional N-path filter, whose out-of-band rejection is given by S₂₁(s)≈Rₒₙ/Rₛ.

The single-ended TLNF (FIG. 5A) has even and odd harmonic pass-bands and potential common-mode noise susceptibility. The fully differential TLNF (FIG. 5B) removes the second harmonic pass-bands and improves common mode noise susceptibility at the cost of double the switch resistance (sacrificing out-of-band rejection).

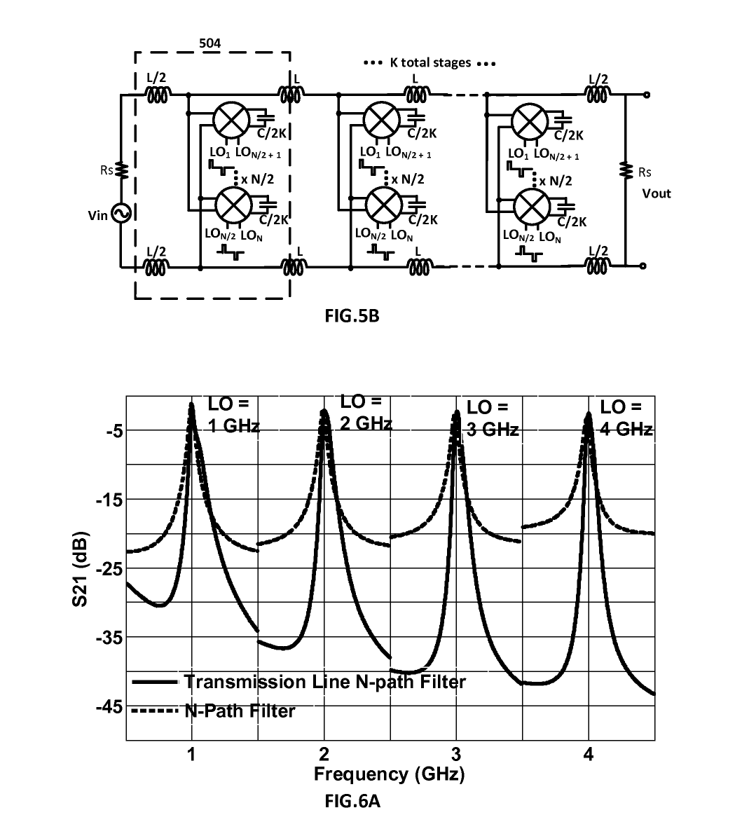

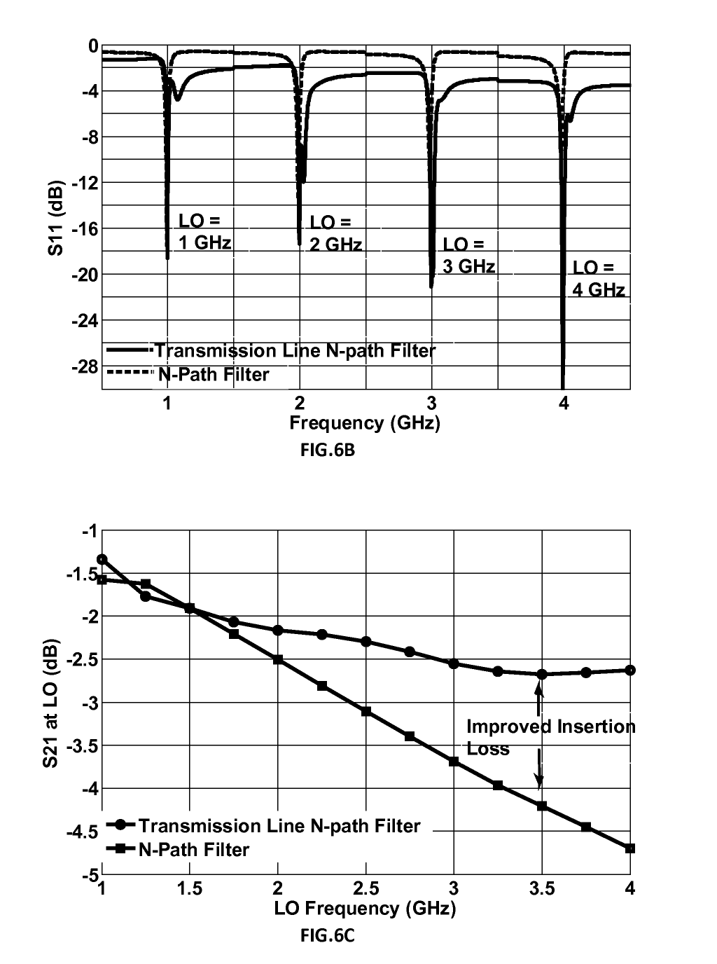

An example plot of the S₂₁ response for the traditional N-path filter (FIG. 1A) and the single-ended TLNF (FIG. 5A) with K=4 is shown in FIG. 6A. As can be seen in FIG. 6A, the single-ended TLNF improves both the insertion loss and out-of-band rejection increasing the frequency range of operation of the traditional N-path filter.

An example plot of the S₁₁ response of the traditional N-path filter (FIG. 1A) and the single-ended TLNF (FIG. 5A) with K=4 is shown in FIG. 6B. As can be seen in FIG. 6B, the parasitic capacitance of the traditional N-path filter shifts the input matching creating a poor, asymmetrical input power match. The TLNF improves the input power match centering the response about the LO clock frequency.

An example plot of the S₂₁ response at LO (or, in-band insertion loss) for the traditional N-path filter (FIG. 1A) and single-ended TLNF (FIG. 5A) with K=4 is shown in FIG. 6C. As can be seen in FIG. 6C, the TLNF improves the insertion loss compared to the N-path filter which has an insertion loss proportional to 1/(1+sRₛNCₚₐᵣ).

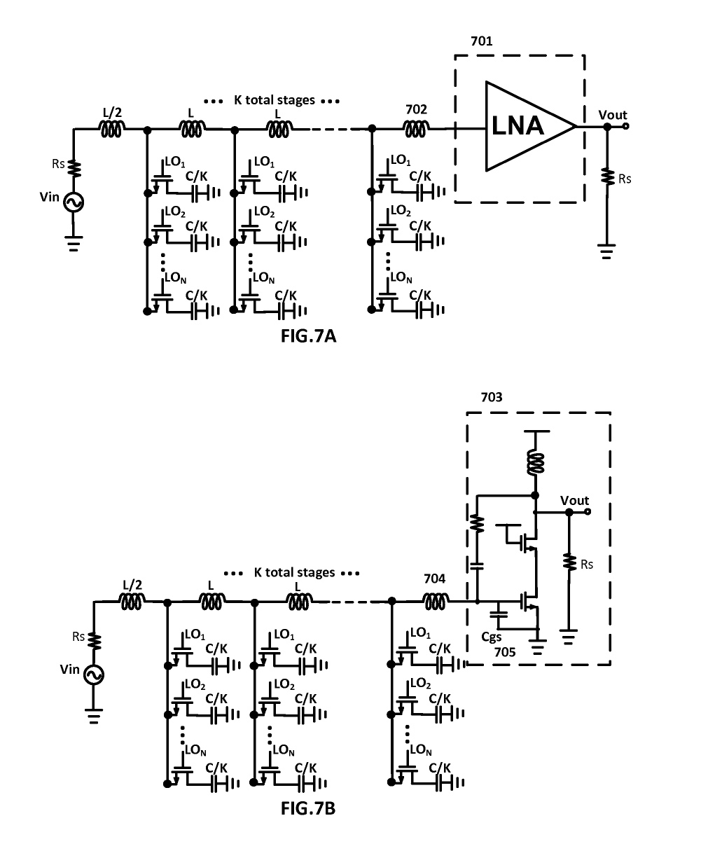

Additionally, a broad-band Low Noise Amplifier (LNA) may be added to the output of the TLNF to create low noise amplification of the desired band as in FIG. 7A. The input parasitic capacitance of the LNA may also be absorbed into the lumped transmission line with appropriately sized inductor. An example embodiment of a single-ended TLNF with broad-band resistive feed-back LNA 703 is shown in FIG. 7B with TLNF stage inductance with additional inductance 704 to absorb the Cgs parasitic input LNA capacitance 705.

A distributed transmission line N-path filter technique improves the high frequency response of the traditional N-path filter. Simulations presented in a bulk CMOS 65 nm process comparing the conventional N-path filter to the distributed transmission line N-path filter demonstrate that the distributed transmission line N-path filter is superior to the traditional N-path filter high frequency performance in terms of insertion loss and out-of-band rejection.

In an example embodiment, a single-ended four-stage (K=4) TLNF was designed with a cut-off frequency below 3 GHz, followed by a broad-band resistive feed-back CMOS LNA. A divide-by-four divider with clock retiming creates the non-overlapping 8-phase clock for an N=8 N-path filter. The example chip was implemented in a 65 nm bulk CMOS process.

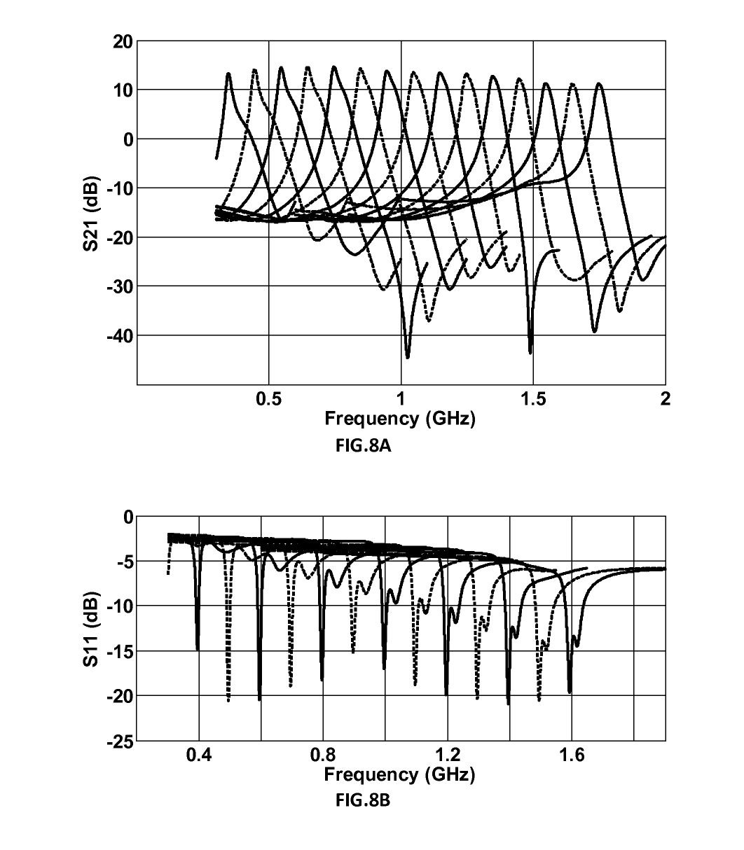

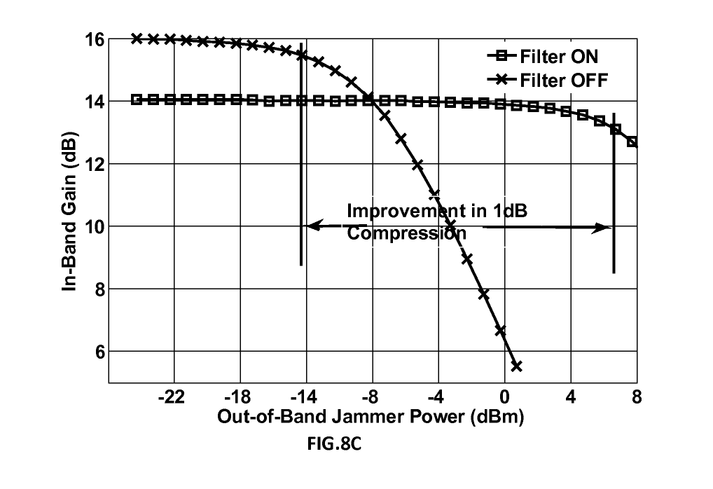

The measured S-parameters for the example chip are shown in FIGS. 8A and 8B. In particular, FIG. 8A illustrates an example measured S₂₁ response and FIG. 8B illustrates an example measured S₁₁. Measurements demonstrate the example TLNF shows a best case out-of-band rejection of approximately 52 dB and jammer power handling capability of +7 dBm. The measured out-of-band jammer P1dB compression is shown in FIG. 8C. FIG. 8C illustrates an example measured filter/LNA gain compression at 1 GHz with out-of-band jammer at 230 MHz offset. As shown, a 19 dB improvement in P1dB compression is achieved in this example.

The proposed Transmission Line N-path Filter (TLNF) technique absorbs the shunt parasitic capacitance of the N-path filter into a transmission line, reducing in-band insertion loss and increases out-of-band rejection by further low-pass filtering created by the switch Rₒₙ resistance and the transmission line inductance.

While this invention has been particularly shown and described with references to example embodiments thereof, it will be understood by those skilled in the art that various changes in form and details may be made therein without departing from the scope of the invention encompassed by the appended claims.

What is claimed is:

1. A single-ended transmission line N-path filter comprising:
one or more filter stages, each stage comprising a first series inductive element, a shunt N-path filter, and a second series inductive element;
an input port; and
an output port.

2. The single-ended filter of claim 1 in which each N-path filter is driven by non-overlapping clocks.

3. The single-ended filter of claim 1 in which each inductive element comprises a spiral inductor.

4. The single-ended filter of claim 1 in which each inductive element comprises a waveguide inductor.

5. A differential transmission line N-path filter comprising:
one or more filter stages, each stage comprising a first leg having a first inductive element connected in series with a second inductive element at a first node, a second leg running parallel to the first leg, the second leg having a third inductive element connected in series with a fourth inductive element at a second node, and a differential shunt N-path filter connected between the first node of the first leg and the second node of the second leg;
an input port; and
an output port.

6. The differential filter of claim 5 in which each N-path filter is driven by non-overlapping clocks.

7. The differential filter of claim 5 in which each inductive element comprises a spiral inductor.

8. The differential filter of claim 5 in which each inductive element comprises a waveguide inductor.

9. A circuit comprising:
a transmission line N-path filter comprising an input port, and output port, and one or more filter stages; and
a low noise amplifier connected to the output port of the transmission line N-path filter.

10. The circuit of claim 9 in which the transmission line N-path filter is a single-ended filter and each filter stage comprises a first series inductive element, a shunt N-path filter, and a second series inductive element.

11. The circuit of claim 10 in which each N-path filter is driven by non-overlapping clocks.

12. The circuit of claim 10 in which each inductive element comprises a spiral inductor.

13. The circuit of claim 10 in which each inductive element comprises a waveguide inductor.

14. The circuit of claim 9 in which the transmission line N-path filter is a differential filter and each filter stage comprises a first leg having a first inductive element connected in series with a second inductive element at a first node, a second leg running parallel to the first leg, the second leg having a third inductive element connected in series with a fourth inductive element at a second node, and a differential shunt N-path filter connected between the first node of the first leg and the second node of the second leg.

15. The circuit of claim 14 in which each N-path filter is driven by non-overlapping clocks.

16. The circuit of claim 14 in which each inductive element comprises a spiral inductor.

17. The circuit of claim 14 in which each inductive element comprises a waveguide inductor.
